(19) United States
(12) Patent Application Publication
(10) Pub. No.: US 2024/0112891 A1
(43) Pub. Date: Apr. 4, 2024

(54) PLASMA PROCESSING APPARATUS AND SUBSTRATE PROCESSING APPARATUS

(71) Applicant: Tokyo Electron Limited, Tokyo (JP)

(72) Inventors: Masaru ISAGO, Miyagi (JP); Ryoya ABE, Miyagi (JP)

(73) Assignee: Tokyo Electron Limited, Tokyo (JP)

(21) Appl. No.: 18/374,679

(22) Filed: Sep. 29, 2023

(30) Foreign Application Priority Data
Sep. 29, 2022 (JP) 2022-156552
Aug. 7, 2023 (JP) 2023-128762

(51) Int. Cl. H01J 37/32

(52) U.S. Cl. CPC H01J 37/32467; H01J 37/32091; H01J 37/3244; H01J 37/32642

(57) ABSTRACT

There is a plasma processing apparatus comprising: a conductive chamber made of a first conductive material and connected to a ground potential; a plasma generator configured to generate a plasma in the conductive chamber; a plurality of conductive liners made of a second conductive material different from the first conductive material and arranged in a circumferential direction in the conductive chamber, each conductive liner having a first surface and a second surface opposite to the first surface, the first surface being in contact with a sidewall of the conductive chamber, the second surface being exposed to the plasma, a gap being formed between two adjacent conductive liners among the plurality of conductive liners; and a plurality of fixing mechanisms respectively corresponding to the plurality of conductive liners, each fixing mechanism being configured to fix a corresponding conductive liner to the sidewall of the conductive chamber.

### CROSS-REFERENCE TO RELATED APPLICATIONS

This application claims priority to Japanese Patent Application Nos. 2022-156552, filed on Sep. 29, 2022 and 2023-128762, filed on Aug. 7, 2023, the entire contents of which are incorporated herein by reference.

### Technical Field

The present disclosure relates to a plasma processing apparatus and a substrate processing apparatus.

### BACKGROUND

U.S. Patent Application Publication No. 2020/0075295 discloses a confinement ring disposed in a chamber of a substrate processing system. The confinement ring is disposed to confine plasma in a plasma region. The confinement ring includes an annular lower wall, an outer wall, and an upper wall.

### SUMMARY

The technique of the present disclosure provides a liner structure suitable for a chamber of a processing apparatus.

In accordance with an exemplary embodiment of the present disclosure, there is a plasma processing apparatus comprising: a conductive chamber made of a first conductive material and connected to a ground potential; a plasma generator configured to generate a plasma in the conductive chamber; a plurality of conductive liners made of a second conductive material different from the first conductive material and arranged in a circumferential direction in the conductive chamber, each conductive liner having a first surface and a second surface opposite to the first surface, the first surface being in contact with a sidewall of the conductive chamber, the second surface being exposed to the plasma, a gap being formed between two adjacent conductive liners among the plurality of conductive liners; and a plurality of fixing mechanisms respectively corresponding to the plurality of conductive liners, each fixing mechanism being configured to fix a corresponding conductive liner to the sidewall of the conductive chamber.

### BRIEF DESCRIPTION OF THE DRAWINGS

FIG. 1 explains a configuration example of a plasma processing system.

FIG. 2 explains a configuration example of a capacitively coupled plasma processing apparatus.

FIG. 3 is a top plan view of a liner assembly and a sidewall of a plasma processing chamber.

FIG. 4 is a plan view showing a gap structure of a liner assembly according to another embodiment.

FIG. 5 is a plan view showing a gap structure of a liner assembly according to still another embodiment.

FIG. 6 is a plan view showing a gap structure of a liner assembly according to further still another embodiment.

FIG. 7 is a side view showing the arrangement of a fixing mechanism in a conductive liner.

FIGS. 8A to 8C explain a fixing structure of the conductive liner and the sidewall using the fixing mechanism.

FIGS. 9A and 9B explain states of the plasma processing chamber and a plurality of conductive liners in the case where the plasma processing chamber is in a low-temperature environment or a high-temperature environment.

FIG. 10 is a side view showing arrangement of a fixing mechanism in a conductive liner in another embodiment.

FIG. 11 is a top plan view of a liner assembly and a sidewall of a plasma processing chamber in accordance with another embodiment.

FIG. 12 is a top plan view of a liner assembly and a sidewall of a plasma processing chamber in accordance with still another embodiment.

FIG. 13 is a top plan view of a liner assembly and a sidewall of a plasma processing chamber in accordance with further still another embodiment.

FIGS. 14A and 14B explain a fixing structure of the conductive liner and the sidewall by the fixing mechanism in another embodiment.

### DETAILED DESCRIPTION

In a semiconductor device manufacturing process, plasma processing such as etching, film formation, or the like is performed on a semiconductor substrate (hereinafter, referred to as “substrate”) in a plasma processing apparatus. In the plasma processing, plasma is generated by exciting a processing gas, and the substrate is processed by the plasma.

The plasma processing apparatus has a plasma processing space formed within a chamber. Further, the plasma processing apparatus is provided with a liner for confining a plasma in the plasma processing space. In the chamber, the liner is in contact with the chamber. The outer wall of the confinement ring in the above-described U.S. Patent Application Publication No. 2020/0075295 corresponds to the liner.

The liner is made of Si or SiC, for example. When Si or SiC is used, excellent plasma uniformity can be obtained and particle generation can be suppressed. The chamber is made of, Al, for example, in view of a manufacturing cost and processability. In other words, the chamber made of Al is disposed on an outer peripheral side, and the liner made of Si or SiC is disposed on an inner peripheral side. In this case, Si or SiC and Al have different linear expansion coefficients. Therefore, when the plasma processing is performed at a desired temperature, radial dimensions of the liner and the chamber may change and, thus, the contact between the liner and the chamber may not be maintained. Accordingly, thermal conduction and electrical connection between the liner and the chamber cannot be ensured. Hence, the structure of the conventional liner needs to be improved.

The technique of the present disclosure has been made in view of the above circumstances, and provides a liner structure suitable for a chamber of a processing apparatus. Hereinafter, a plasma processing apparatus according to an embodiment will be described with reference to the accompanying drawings. Like reference numerals will be given to like parts having substantially the same functions and configurations throughout the present specification and the drawings, and redundant description thereof will be omitted.

<Plasma Processing System>

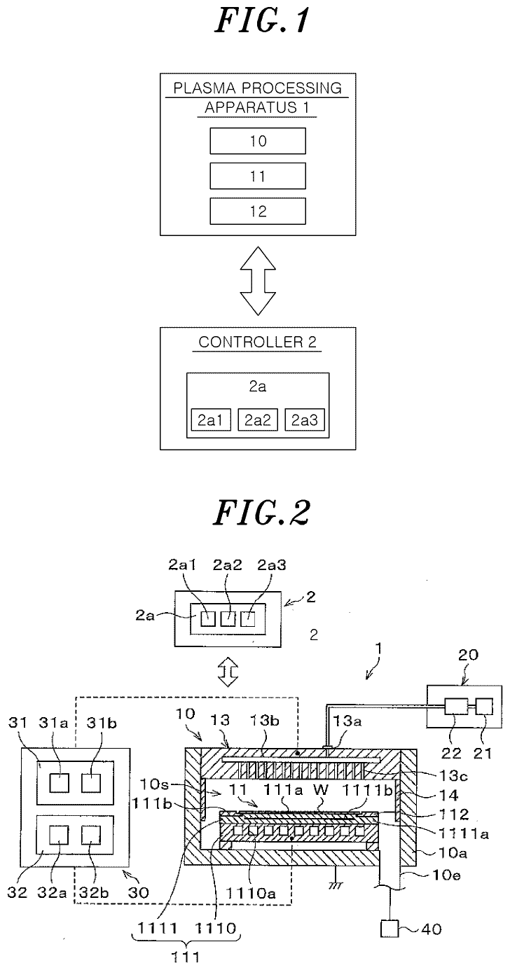

First, a plasma processing system according to one embodiment will be described. FIG. 1 explains a configuration example of the plasma processing system.

In one embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 further has at least one gas inlet for supplying at least one processing gas to the plasma processing space and at least one gas outlet for exhausting a gas from the plasma processing space. The gas inlet is connected to a gas supply 20 to be described later, and the gas outlet is connected to an exhaust system 40 to be described later. The substrate support 11 is disposed in the plasma processing space, and has a substrate support surface for supporting a substrate.

The plasma generator 12 is configured to generate a plasma from at least one processing gas supplied into the plasma processing space. The plasma generated in the plasma processing space includes a capacitively coupled plasma (CCP), an inductively coupled plasma (ICP), an electron-cyclotron-resonance (ECR) plasma, a helicon wave excited plasma (HWP), a surface wave plasma (SWP), or the like. Various types of plasma generators including alternating current (AC) plasma generators and direct current (DC) plasma generators may also be used. In one embodiment, an AC signal (AC power) used in the AC plasma generator has a frequency within a range of 100 kHz to 10 GHz. Therefore, the AC signal includes a radio frequency (RF) signal and a microwave signal. In one embodiment, the RF signal has a frequency within a range of 100 kHz to 150 MHz.

The controller 2 processes computer-executable instructions that cause the plasma processing apparatus 1 to perform various steps described in the present disclosure. The controller 2 may be configured to control individual components of the plasma processing apparatus 1 to perform various steps described herein. In one embodiment, the controller 2 may be partially or entirely included in the plasma processing apparatus 1. The controller 2 may include a processor 2a1, a storage 2a2, and a communication interface 2a3. The controller 2 is realized by a computer 2a, for example. The processor 2a1 may be configured to perform various control operations by reading a program from storage 2a2 and executing the read program. The program may be stored in the storage 2a2 in advance, or may be acquired via a medium when necessary. The acquired program is stored in the storage 2a2, read from the storage 2a2, and executed by the processor 2a1. The medium may be various storage media readable by the computer 2a, or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN) or the like.

<Plasma Processing Apparatus>

Hereinafter, a configuration example of a capacitively coupled plasma processing apparatus as an example of the plasma processing apparatus 1 will be described. FIG. 2 explains a configuration example of a capacitively coupled plasma processing apparatus.

The capacitively coupled plasma processing apparatus 1 includes the plasma processing chamber 10, the gas supply 20, a power supply 30, and the exhaust system 40. The plasma processing apparatus 1 further includes the substrate support 11 and a gas introducing unit. The gas introducing unit is configured to introduce at least one processing gas into the plasma processing chamber 10. The gas introducing unit includes a showerhead 13. The substrate support 11 is disposed in the plasma processing chamber 10. The showerhead 13 is disposed above the substrate support 11. In one embodiment, the showerhead 13 forms at least a part of the ceiling of plasma processing chamber 10. The plasma processing chamber 10 has a plasma processing space 10s defined by the showerhead 13, a sidewall 10a of the plasma processing chamber 10, and the substrate support 11. The plasma processing chamber 10 is connected to a ground potential. The showerhead 13 and the substrate support 11 are electrically insulated from the housing of the plasma processing chamber 10.

Further, the plasma processing apparatus 1 includes a liner assembly 14. The liner assembly 14 is formed in an annular shape along the sidewall (inner wall) 10a of the plasma processing chamber 10. The liner assembly 14 is disposed to confine the plasma in the plasma processing space 10s. A baffle assembly may be formed in an annular shape between the substrate support 11 and the liner assembly 14. The baffle assembly is disposed to exhaust a gas in the plasma processing space 10s.

The substrate support 11 includes a main body 111 and a ring assembly 112. The main body 111 has a central region 111a for supporting a substrate W and an annular region 111b for supporting the ring assembly 112. A wafer is an example of a substrate W. The annular region 111b of the main body 111 surrounds the central region 111a of the main body 111 in plan view. The substrate W is disposed on the central region 111a of the main body 111, and the ring assembly 112 is arranged on the annular region 111b of the main body 111 to surround the substrate W on the central region 111a of the main body 111. Accordingly, the central region 111a is also referred to as “substrate support surface” for supporting the substrate W, and the annular region 111b is also referred to as “ring support surface” for supporting the ring assembly 112.

In one embodiment, the main body 111 includes a base 1110 and an electrostatic chuck 1111. The base 1110 includes a conductive member. The conductive member of the base 1110 may serve as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In one embodiment, the ceramic member 1111a also has the annular region 111b. Another member surrounding the electrostatic chuck 1111, such as an annular electrostatic chuck or an annular insulating member, may have the annular region 111b. In this case, the ring assembly 112 may be placed on the annular electrostatic chuck or the annular insulating member, or may be placed on both the electrostatic chuck 1111 and the annular insulating member. Further, at least one RF/DC electrode connected to an RF power source 31 and/or a DC power source 32, which will be described later, may be disposed in the ceramic member 1111a. In this case, at least one RF/DC electrode serves as the lower electrode. If a bias RF signal and/or a DC signal, which will be described later, is applied to at least one RF/DC electrode, the RF/DC electrode is also referred to as “bias electrode.” The conductive member of the base 1110 and at least one RF/DC electrode may serve as a plurality of lower electrodes. The electrostatic electrode 1111b may serve as the lower electrode. Accordingly, the substrate support 11 includes at least one lower electrode.

The ring assembly 112 includes one or more annular members. In one embodiment, one or more annular members include one or more edge rings and at least one cover ring. The edge ring is made of a conductive material or an insulating material, and the cover ring is made of an insulating material.

The substrate support 11 may include a temperature control module configured to control at least one of the electrostatic chuck 1111, the ring assembly 112, and the substrate W to a target temperature. The temperature control module may include a heater, a heat transfer medium, a channel 1110a, or a combination thereof. A heat transfer fluid, such as brine or a gas, flows through the channel 1110a. In one embodiment, the channel 1110a is formed in the base 1110, and one or more heaters are disposed in the ceramic member 1111a of the electrostatic chuck 1111. The substrate support 11 may also include a heat transfer gas supply configured to supply a heat transfer gas to the gap between the backside of the substrate W and the central region 111a.

The showerhead 13 is configured to introduce at least one processing gas from the gas supply 20 into the plasma processing space 10s. The showerhead 13 has at least one gas supply port 13a, at least one gas diffusion space 13b, and a plurality of gas inlet ports 13c. The processing gas supplied to the gas supply port 13a passes through the gas diffusion space 13b and is introduced into the plasma processing space 10s through the gas inlet ports 13c. The showerhead 13 includes at least one upper electrode. The gas introducing unit may include, in addition to the showerhead 13, one or more side gas injectors (SGI) attached to one or more openings formed in the sidewall 10a.

The gas supply 20 may include at least one gas source 21 and at least one flow controller 22. In one embodiment, the gas supply 20 is configured to supply at least one processing gas from the corresponding gas source 21 to the showerhead 13 through the corresponding flow controller 22. The flow controllers 22 may include, for example, a mass flow controller or a pressure-controlled flow controller. Further, the gas supply 20 may include one or more flow modulation device for modulating or pulsing the flow of at least one processing gas.

The power supply 30 includes an RF power supply 31 connected to the plasma processing chamber 10 through at least one impedance matching circuit. The RF power supply 31 is configured to supply at least one RF signal (RF power) to at least one lower electrode and/or at least one upper electrode. Accordingly, plasma is produced from at least one processing gas supplied to the plasma processing space 10s. Therefore, the RF power supply 31 may serve as at least a part of the plasma generator 12. Further, by supplying a bias RF signal to at least one lower electrode, a bias potential is generated at the substrate W, and ions in the produced plasma can be attached to the substrate W.

In one embodiment, the RF power supply 31 includes a first RF generator 31a and a second RF generator 31b. The first RF generator 31a is connected to at least one lower electrode and/or at least one upper electrode through at least one impedance matching circuit to generate a source RF signal (source RF power) for plasma generation. In one embodiment, the source RF signal has a frequency within a range of 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is connected to at least one lower electrode through at least one impedance matching circuit and configured to generate a bias RF signal (bias RF power). The frequency of the bias RF signal may be the same as or different from the frequency of the source RF signal. In one embodiment, the bias RF signal has a frequency lower than the frequency of the source RF signal. In one embodiment, the bias RF signal has a frequency within a range of 100 kHz to 60 MHz. In one embodiment, the second RF generator 31b may be configured to generate a plurality of bias RF signals having different frequencies. The generated one or more bias RF signals are supplied to at least one lower electrode. In various embodiments, at least one of the source RF signal and the bias RF signal may pulsate.

Further, the power supply 30 may include the DC power supply 32 connected to plasma processing chamber 10. The DC power supply 32 includes a first DC generator 32a and a second DC generator 32b. In one embodiment, the first DC generator 32a is connected to the at least one lower electrode and configured to generate a first DC signal. The generated first DC signal is applied to at least one lower electrode. In one embodiment, the second DC generator 32b is connected to the at least one upper electrode and configured to generate a second DC signal. The generated second DC signal is applied to at least one upper electrode.

In various embodiments, the first and second DC signals may pulsate. In this case, a sequence of voltage pulses is applied to at least one lower electrode and/or at least one upper electrode. The voltage pulse may have a rectangular pulse waveform, a trapezoidal pulse waveform, a triangular pulse waveform, or a combination thereof. In one embodiment, a waveform generator for generating a sequence of voltage pulses from the DC signal is connected between the first DC generator 32a and the at least one lower electrode. Therefore, the first DC generator 32a and the waveform generator constitute a voltage pulse generator. When the second DC generator 32b and the waveform generator constitute the voltage pulse generator, the voltage pulse generator is connected to at least one upper electrode. The voltage pulse may have positive polarity or negative polarity. The sequence of voltage pulses may include one or more positive voltage pulses and one or more negative voltage pulses in one cycle. The first DC generator 32a and the second DC generator 32b may be provided in addition to the RF power supply 31, and the first DC generator 32a may be provided instead of the second RF generator 31b.

The exhaust system 40 may be connected to a gas exhaust port 10e disposed at the bottom portion of the plasma processing chamber 10, for example. The exhaust system 40 may include a pressure control valve and a vacuum pump. The pressure control valve adjusts a pressure in the plasma processing space 10s. The vacuum pump may include a turbo molecular pump, a dry pump, or a combination thereof.

<Plasma Processing Chamber and Liner Assembly>

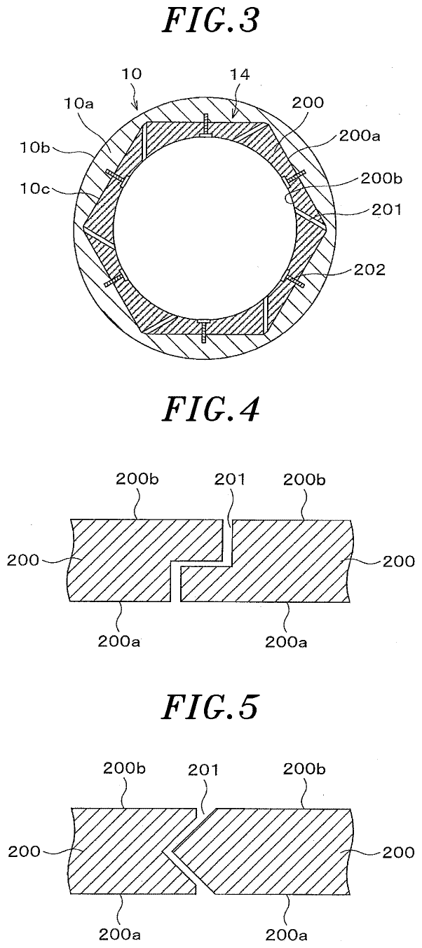

Next, the configuration of the plasma processing chamber 10 and the liner assembly 14 described above will be described. FIG. 3 is a top plan view of the liner assembly 14 and the sidewall 10a of plasma processing chamber 10.

The plasma processing chamber 10 is a conductive chamber, and is made of a first conductive material. The first conductive material is a metal such as Al, Ti, W, or the like. The plasma processing chamber 10 is connected to the ground potential.

The outer surface 10b of the sidewall 10a of the plasma processing chamber 10 has a circular shape in plan view. An inner surface 10c of the sidewall 10a has a plurality of flat surfaces. In the present embodiment, the inner surface 10c has six flat surfaces. In other words, the inner surface 10c has a hexagonal shape in plan view. The number of flat surfaces of the inner surface 10c is arbitrary. The inner surface 10c is in contact with a first surface 200a of the conductive liner 200, as will be described below, and the number of flat surfaces of the inner surface is the same as the number of first surfaces 200a.

The liner assembly 14 has a structure in which an annular shape is divided, and has a plurality of conductive liners 200. The conductive liners 200 are made of a second conductive material different from the first conductive material. In one embodiment, the second conductive material is Si or SiC. In one embodiment, the second conductive material is carbon, titanium, tungsten, or Hastelloy. The conductive liners 200 are connected to the ground potential through the plasma processing chamber 10. In other words, the conductive liners 200 serve as a path to the ground potential.

The conductive liners 200 have an annular shape as a whole in plan view, and are arranged along the sidewall 10a of the plasma processing chamber 10 in a circumferential direction. The conductive liners 200 are in contact with the sidewall 10a. In the present embodiment, six conductive liners 200 are provided, and they are arranged at substantially regular intervals. In other words, the conductive liner 200 have substantially the same dimension in plan view. The number of conductive liners 200 is arbitrary, and preferably 3 to 30, for example.

The first surface (outer surface) 200a of the conductive liner 200 is a flat surface and is in contact with the inner surface 10c of the sidewall 10a. A second surface (inner surface) 200b opposite to the first surface 200a of the conductive liner 200 is exposed to the plasma processing space 10s. Therefore, the second surface 200b is exposed to plasma generated in the plasma processing space 10s. The second surface 200b has a first curvature in plan view. The first curvature allows the second surfaces 200b of the conductive liners 200 to have a circular shape as a whole in plan view.

A window (not shown) or a shutter (not shown) may be disposed below one of the conductive liners 200.

A gap 201 is formed between two adjacent conductive liners 200 among the plurality of conductive liners 200. In the present embodiment, six gaps 201 are formed in the six conductive liners 200. Due to the presence of the gaps 201, the interference between two adjacent conductive liners 200 can be suppressed even if the two adjacent conductive liners 200 are thermally expanded.

Here, if the gap between the conductive liners 200 is formed in a diametrical direction, i.e., radially, the inner surface 10c of the sidewall 10a is exposed to plasma, which may result in abnormal discharge. In this regard, if the gap is formed in an elongated shape in the diametrical direction, the probability in which plasma reaches the inner surface 10c can be reduced, and the possibility of abnormal discharge can be reduced.

On the other hand, in order to further suppress abnormal discharge, it is preferable that the gaps 201 are formed diagonally with respect to the diametrical direction as in the present embodiment. In this case, the inner surface 10c of the sidewall 10a is not exposed to the plasma processing space 10s, and the exposure of the inner surface 10c to plasma can be suppressed. Accordingly, abnormal discharge can be suppressed.

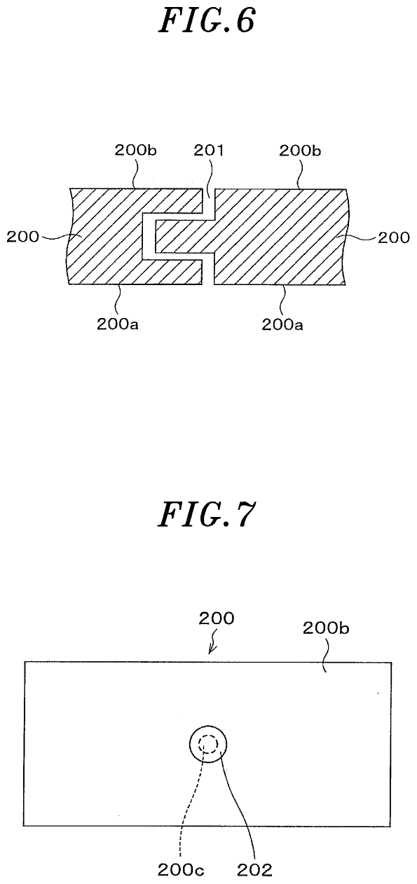

The configuration of the gap 201 is not limited to that in the present embodiment. The gap 201 may have any configuration as long as it suppresses the exposure of the inner surface 10c of the sidewall 10a to the plasma. For example, as shown in FIGS. 4 to 6, the gap 201 may have a labyrinth-shaped structure (labyrinth structure) having a plurality of folded portions. As shown in FIG. 4, the labyrinth structure may be formed by forming a rectangular irregularity on the side surface of the conductive liner 200 and arranging a convex portion of one liner at a concave portion of another liner. As shown in FIG. 5, a labyrinth structure may be formed by forming an angular (triangular in the illustrated example) irregularity on the side surface of the conductive liner 200. As shown in FIG. 6, the labyrinth structure may be formed by forming a plurality of irregularities on the side surface of the conductive liner 200. Any labyrinth structure can suppress the exposure of the inner surface 10c of the sidewall 10a to plasma, and suppress abnormal discharge.

The plasma processing apparatus 1 includes a plurality of fixing mechanisms respectively corresponding to the plurality of conductive liners 200. Each fixing mechanism is configured to fix the corresponding conductive liner 200 to the sidewall (inner wall) 10a of the plasma processing chamber 10. The fixing mechanism includes at least one fixing member 202. In one embodiment, the fixing mechanism includes one fixing member 202, and each conductive liner 200 is fixed to the sidewall 10a of the plasma processing chamber 10 by the fixing member 202, as shown in FIG. 3. The fixing member 202 fixes the conductive liner 200 to the sidewall 10a in a state where the gap 201 is formed between two adjacent conductive liners 200 and the first surface 200a of the conductive liner 200 and the inner surface 10c of the sidewall 10a are in contact with each other.

In the example shown in FIG. 3, the fixing member 202 is a bolt. In one embodiment, the bolt 202 fixes the conductive liner 200 to the sidewall 10a from the conductive liner 200 side. In other words, the head of bolt 202 is disposed in the conductive liner 200. Further, as shown in FIG. 7, the fixing member 202 is disposed substantially at the center of the conductive liner 200 in a horizontal direction.

The material of the fixing member 202 is not particularly limited, and may be a metal, ceramic, resin, quartz, or the like. Here, in order to obtain stable contact between the conductive liner 200 and the sidewall 10a, it is necessary to maintain a surface pressure between the first surface 200a and the inner surface 10c, and the fixing member 202 requires an axial force for maintaining the surface pressure. Since the axial force of the fixing member 202 is determined by the design, the material of the fixing member 202 is not particularly limited as long as the required axial force can be obtained. However, it is preferable that the fixing member 202 is made of a metal in order to easily obtain the axial force.

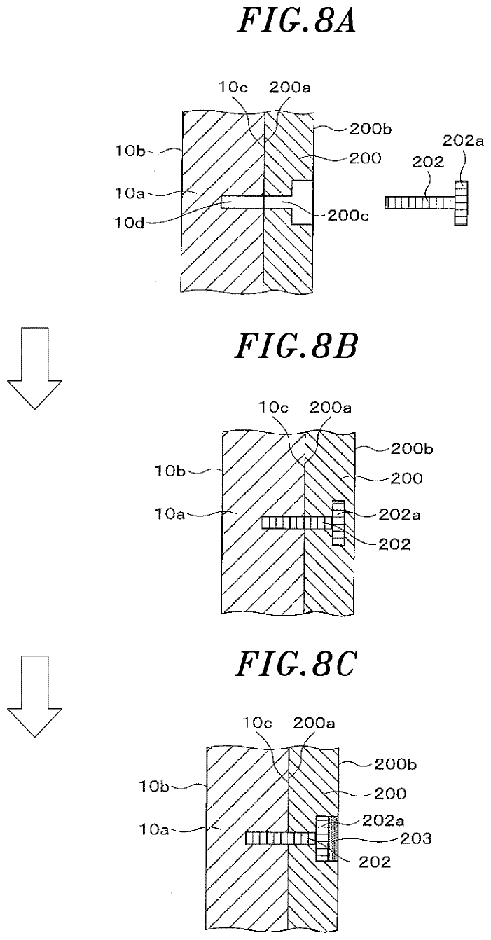

FIGS. 8A to 8C specifically show the fixing structure of the conductive liner 200 and the sidewall 10a using the bolt 202. As shown in FIG. 8A, the conductive liner 200 has a through hole 200c penetrating from the first surface 200a to the second surface 200b. As shown in FIG. 7, the through hole 200c is formed substantially at the center of the conductive liner 200 in the horizontal direction. A bolt hole 10d is formed in the inner surface 10c of the sidewall 10a. The bolt hole 10d of the sidewall 10a communicates with the through hole 200c of the conductive liner 200. As shown in FIG. 8B, the bolt 202 is attached to the bolt hole 10d through the through hole 200c to fix the conductive liner 200 and the sidewall 10a. A nut may be disposed at the bottom portion of the bolt hole 10d. In this case, the conductive liner 200 is fixed to the sidewall 10a by attaching the bolt 202 to the nut.

If the bolt 202 is made of, for example, a metal with low plasma resistance, a cap 203 is disposed to cover the head 202a of the bolt 202 as shown in FIG. 8C. The cap 203 is made of a plasma resistant material such as Si. A method for forming the cap 203 is not particularly limited. An Si cover plate may be fitted, or an Si material may be thermally sprayed. The cap 203 may not be provided when the bolt 202 is made of, for example, ceramic with high plasma resistance.

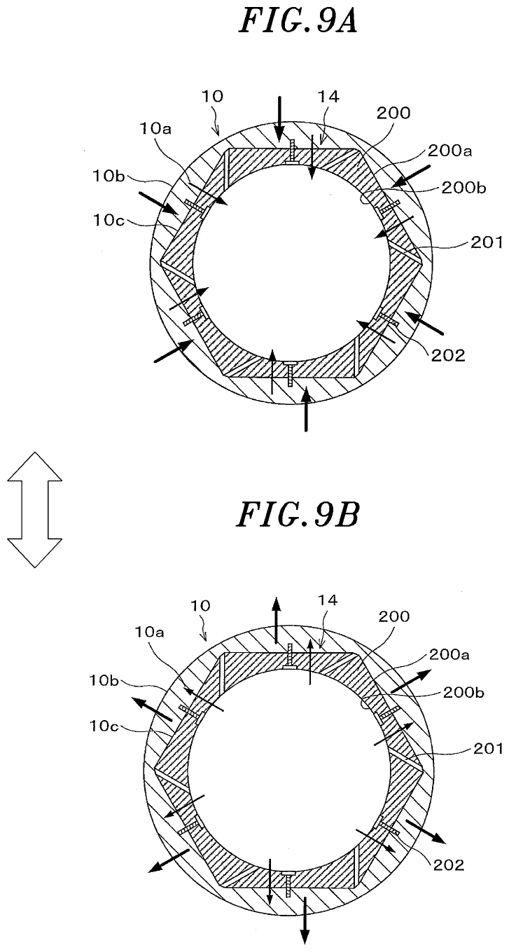

FIG. 9A shows the plasma processing chamber 10 and the plurality of conductive liners 200 in a case where the plasma processing chamber 10 is in a low-temperature environment. FIG. 9B shows the plasma processing chamber 10 and the plurality of conductive liners 200 in a case where the plasma processing chamber 10 is in a high-temperature environment. A low temperature is a temperature range in which the linear expansion difference between Al forming the plasma processing chamber 10 and Si or SiC forming the conductive liner 200 is small. A high temperature is several hundreds of degrees (° C.), for example, and is a temperature range in which the linear expansion difference between the plasma processing chamber 10 and the conductive liner 200 is large.

As shown in FIG. 9A, in the low-temperature environment, the linear expansion difference between the plasma processing chamber 10 and the conductive liner 200 is small, and the contact between the inner surface 10c of the sidewall 10a and the first surface 20a of the conductive liner 200 is maintained. In this case, the gap 201 between two adjacent conductive liners 200 is small.

On the other hand, as shown in FIG. 9B, in the high-temperature environment in which a temperature in the plasma processing chamber 10 has increased, the linear expansion difference between the plasma processing chamber 10 and the conductive liner 200 is large. Specifically, the linear expansion in the radial direction of the sidewall 10a is large (indicated by thick arrows in the drawing), and the linear expansion of the conductive liner 200 in the radial direction is small (indicated by thin arrows in the drawing). Even in this case, the conductive liner 200 is fixed to the sidewall 10a by the fixing member 202, so that the conductive liner 200 conforms to the sidewall 10a. Accordingly, the contact between the inner surface 10c of the sidewall 10a and the first surface 20a of the conductive liner 200 is maintained.

Further, the linear expansion of the sidewall 10a in the circumferential direction is large, and the linear expansion of the conductive liner 200 in the circumferential direction is small. Even in this case, the liner assembly 14 has a structure divided into the plurality of conductive liners 200, so that the gaps 201 are large but the contact between the inner surface 10c of the sidewall 10a and the first surface 20a of the conductive liner 200 is maintained. Accordingly, in accordance with the present embodiment, the liner assembly 14 has a structure divided into the plurality of conductive liners 200, and the conductive liners 200 are fixed to the sidewall 10a by the fixing member 202, which makes it possible to maintain the contact between the sidewall 10a and the conductive liners 200. Hence, thermal conduction and electrical connection between the sidewall 10a and the conductive liners 200 can be maintained.

Further, the inner surface 10c of the sidewall 10a and the first surface 200a of the conductive liner 200 are flat surfaces, and are in surface contact with each other. Therefore, even in a high-temperature environment, the surface contact (tangent surface) between the inner surface 10c and the first surface 200a can be maintained.

Here, for example, when the conductive liner 200 is fixed to the sidewall 10a at a location distant from the substantially center in the horizontal direction, the fixing member 202 and the conductive liner 200 may interfere with each other due to the linear expansion difference between the sidewall 10a and the conductive liner 200 in a high-temperature environment. In this case, the damage such as cracks or the like may occur in the conductive liner 200. In this regard, as shown in FIG. 7, the fixing member 202 is disposed substantially at the center of the conductive liner 200 in the horizontal direction, and the conductive liner 200 is fixed to the sidewall 10a at its center without being fixed to the sidewall 10a at a location distant from its center. Therefore, there is no influence of the linear expansion difference, and the damage to the conductive liner 200, such as cracks or the like, can be avoided.

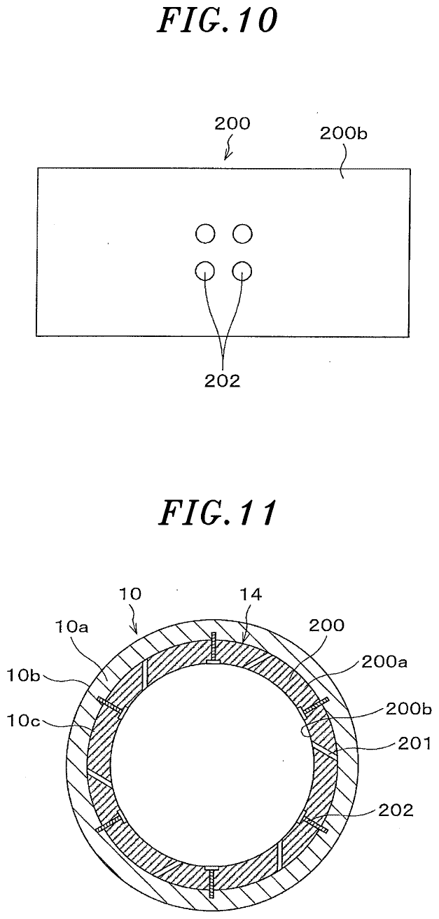

In the present embodiment, one fixing member 202 is disposed substantially at the center of the conductive liner 200 in the horizontal direction, but the number of the fixing member 202 is not limited thereto. In other words, in one embodiment, the fixing member for fixing one conductive liner 200 includes a plurality of fixing members 202. As shown in FIG. 10, a plurality of fixing members 202, for example, four fixing members 202 in one example, may be disposed around the center of the conductive liner 200 in the horizontal direction. In this case, the contact pressure between the conductive liner 200 and the sidewall 10a by the plurality of fixing members 202 can be improved, and the conductive liner 200 can be stably fixed.

However, the plurality of fixing members 202 are disposed substantially at the center of the conductive liner 200 in the horizontal direction within a range in which the fixing members 202 and the conductive liner 200 do not interfere with each other in a high-temperature environment, that is, within a range in which the damage such as cracks or the like does not occur in the conductive liner 200. The allowable range of the installation position of the fixing member 202 from the substantial center of the conductive liner 200 in the horizontal direction depends on the linear expansion difference. In other words, it depends on the setting of the temperature in the plasma processing chamber 10. For example, as the temperature is higher, the allowable range is narrower, and as the temperature is lower, the allowable range is wider.

Although the fixing member 202 is a bolt in the present embodiment, the configuration of the fixing member 202 is not limited thereto. For example, the fixing members 202 may be a screw other than a bolt. Further, for example, the fixing mechanism may have a clamp structure. In this case, the fixing mechanism of the clamp structure is disposed in a height direction at the substantially center of the conductive liner 200 in the horizontal direction. The fixing mechanism may clamp the upper end the lower end of the conductive liner 200, or may clamp the conductive liner 200 from the upper end to the lower end thereof.

Next, the configuration of the plasma processing chamber 10 and the liner assembly 14 according to another embodiment will be described. FIGS. 11 to 13 are top plan views of the liner assembly 14 and the sidewall 10a of the plasma processing chamber 10.

As shown in FIG. 11, the inner surface 10c of the sidewall 10a of the plasma processing chamber 10 has a circular shape in plan view. The first surface 200a of the conductive liner 200 has a second curvature in plan view. The second curvature allows the first surfaces 200a of the plurality of conductive liners 200 to have a circular shape as a whole in plan view. In other words, the inner surface 10c of the sidewall 10a and the first surface 200a of the conductive liner 200 have the same planar shape, and the inner surface 10c and the first surface 200a are in contact with each other. In the present embodiment, the fixing member 202 fixes the conductive liner 200 and the sidewall 10a from the conductive liner 200 side, as in the above-described embodiment.

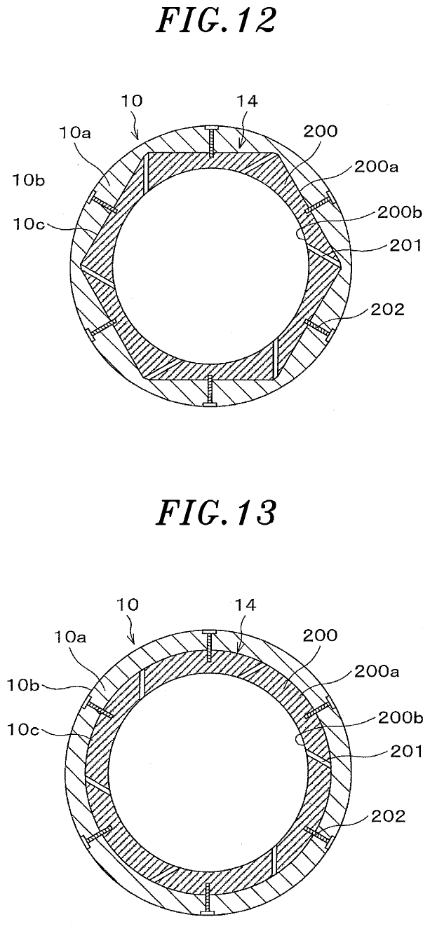

The sidewall 10a and the conductive liner 200 shown in FIG. 12 have the same shape as those of the sidewall 10a and the conductive liner 200 shown in FIG. 3, respectively. In other words, the inner surface 10c of the sidewall 10a has a plurality of flat surfaces, and the first surface 200a of the conductive liner 200 is a flat surface. Further, the sidewall 10a and the conductive liner 200 shown in FIG. 13 have the same shape as those of the sidewall 10a and the conductive liner 200 shown in FIG. 11, respectively. In other words, the inner surface 10c of the sidewall 10a has a circular shape in plan view, and the first surface 200a of the conductive liner 200 has the second curvature in plan view.

In the embodiment shown in FIGS. 3 and 11, the fixing member 202 fixes the conductive liner 200 and the sidewall 10a from the conductive liner 200 side. However, in the embodiment shown in FIGS. 12 and 13, the fixing member 202 fixes the sidewall 10a and the conductive liner 200 from the sidewall 10a side. In other words, the head 202a of the bolt 202 is disposed on the sidewall 10a side.

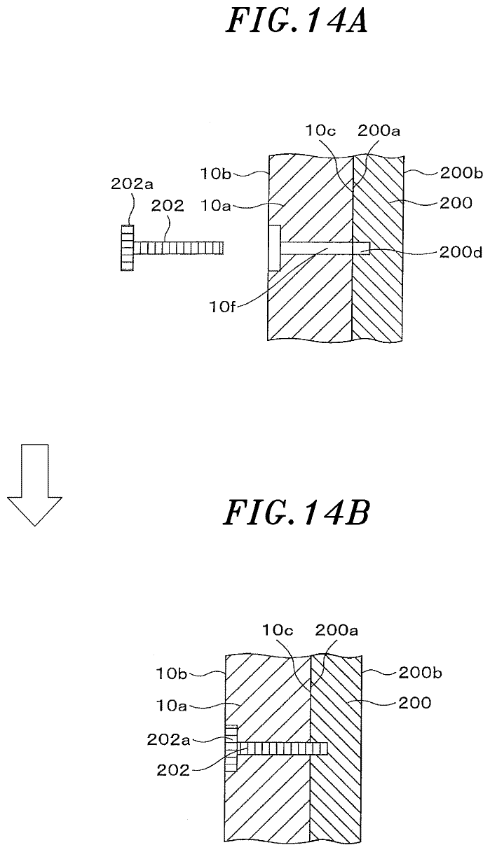

FIGS. 14A and 14B specifically explain the fixing structure of the sidewall 10a and the conductive liner 200 using the bolt 202. As shown in FIG. 14A, the sidewall 10a has a through hole 10f penetrating from the outer surface 10b to the inner surface 10c. The through hole 10f is formed at a position corresponding to substantially the center of the conductive liner 200 in the horizontal direction. Further, a bolt hole 200d is formed in the first surface 200a of the conductive liner 200. The bolt hole 200d of the conductive liner 200 communicates with the through hole 10f of the sidewall 10a. As shown in FIG. 14B, the bolt 202 is attached to the bolt hole 200d through the through hole 10f to fix the sidewall 10a and the conductive liner 200. In this case, the head 202a of the bolt 202 is not exposed to plasma, so that the cap 203 may be omitted regardless of the material of the bolt 202. A nut may be disposed at the bottom portion of the bolt hole 200d. In this case, the conductive liner 200 is fixed to the sidewall 10a by attaching the bolt 202 to the nut.

In any of the cases shown in FIGS. 11 to 13, the same effects as those of the above embodiment can be obtained. In other words, the liner assembly 14 has a structure divided into the plurality of conductive liners 200, and the conductive liners 200 are fixed to the sidewall 10a by the fixing member 202, which makes it possible to maintain the contact between the sidewall 10a and the conductive liners 200.

In the embodiments shown in FIGS. 3 and 11 to 13, a flexible heat transfer member (not shown) may be disposed between the inner surface 10c of the sidewall 10a and the first surface 200a of the conductive liner 200. The heat transfer member is made of graphite, for example. In this case, even if the linear expansion difference between the sidewall 10a and the conductive liner 200 increases in a high-temperature environment, the conformability of the conductive liner 200 to the sidewall 10a can be further improved by the flexible heat transfer member.

In particular, in the embodiments shown in FIGS. 11 and 13, the inner surface 10c of the sidewall 10a and the first surface 200a of the conductive liner 200 have a circular shape, and it is difficult to maintain the surface contact (tangent surface) therebetween compared to the case of a flat surface as in the embodiments shown in FIGS. 3 and 12. Therefore, it is effective to provide a flexible heat transfer member between the inner surface 10c and the first surface 200a.

The plasma processing chamber 10 and the plurality of conductive liners 200 in the above embodiments can also be applied to a substrate processing apparatus other than the plasma processing apparatus 1. For example, the substrate processing apparatus includes a chamber having the same configuration as that of the plasma processing chamber 10, and a plurality of liners having the same configuration as those of the plurality of conductive liners 200. The chamber is made of a metal such as Al, Ti, W, or the like, for example. The liner is made of Si or SiC, for example. In this case, the same effects as those in the above embodiment can be obtained, and even if a linear expansion difference occurs between the chamber and the plurality of liners in a high-temperature environment in the chamber, the contact between the sidewall of the chamber and the liners can be maintained. Therefore, thermal conduction and electrical connection between the sidewall 10a and the conductive liners 200 can be maintained.

In the above embodiments, the plurality of conductive liners 200 in the plasma processing apparatus 1 and the plurality of liners in the substrate processing apparatus are made of Si or SiC, which is a conductive material. However, they may be made of quartz, which is an insulating material. In this case, the same effects as those in the above embodiment can be obtained, and even if a linear expansion difference occurs between the chamber and the plurality of liners in a high-temperature environment in the chamber, the contact between the sidewall of the chamber and the liners can be maintained. Therefore, thermal conduction and electrical connection between the sidewall 10a and the conductive liners 200 can be maintained.

It should be noted that the above-described embodiments are illustrative in all respects and are not restrictive. The above-described embodiments may be omitted, replaced, or changed in various forms without departing from the scope of the appended claims and the gist thereof. For example, the components of the above-described embodiments can be randomly combined. The effects of the components for arbitrary combination can be obtained from the corresponding arbitrary combination, other effects apparent to those skilled in the art can also be obtained.

The effects described in the present specification are merely explanatory or exemplary, and are not restrictive. In other words, in the technique related to the present disclosure, other effects apparent to those skilled in the art can be obtained from the description of the present specification in addition to the above-described effects or instead of the above-described effects.

Further, the following configuration examples are also included in the technical scope of the present disclosure.

(1) A plasma processing apparatus comprising: a conductive chamber made of a first conductive material and connected to a ground potential; a plasma generator configured to generate a plasma in the conductive chamber; a plurality of conductive liners made of a second conductive material different from the first conductive material and arranged in a circumferential direction in the conductive chamber, each conductive liner having a first surface and a second surface opposite to the first surface, the first surface being in contact with a sidewall of the conductive chamber, the second surface being exposed to the plasma, a gap being formed between two adjacent conductive liners among the plurality of conductive liners; and a plurality of fixing mechanisms respectively corresponding to the plurality of conductive liners, each fixing mechanism being configured to fix a corresponding conductive liner to the sidewall of the conductive chamber.

(2) The plasma processing apparatus of (1), wherein the gap is formed obliquely with respect to a radial direction.

(3) The plasma processing apparatus of (1), wherein the gap has a labyrinth-shaped structure having a plurality of folded portions.

(4) The plasma processing apparatus of any one of (1) to (3), wherein the number of the conductive liners is 3 to 30.

(5) The plasma processing apparatus of any one of (1) to (4), wherein the conductive liner has a through hole penetrating from the first surface to the second surface, and the fixing mechanism includes at least one bolt inserted into the through hole.

(6) The plasma processing apparatus of (5), wherein the through hole is formed substantially at a center of the conductive liner in a horizontal direction.

(7) The plasma processing apparatus of any one of (1) to (6), wherein the second surface has a first curvature in plan view.

(8) The plasma processing apparatus of (7), wherein an inner surface of the sidewall of the conductive chamber has a plurality of flat surfaces, and the first surface is a flat surface.

(9) The plasma processing apparatus of (7), wherein an inner surface of the sidewall of the conductive chamber has a circular shape in plan view, and the first surface has a second curvature in plan view.

(10) The plasma processing apparatus of any one of (1) to (9), wherein the second conductive material is Si or SiC.

(11) The plasma processing apparatus of (10), wherein the first conductive material is a metal.

(12) A substrate processing apparatus comprising: a chamber made of a metal and connected to a ground potential; a plurality of liners made of Si or SiC and arranged in a circumferential direction in the chamber, each liner having a first surface and a second surface opposite to the first surface, the first surface being in contact with a sidewall of the chamber, a gap being formed between two adjacent lines among the plurality of liners; and a plurality of fixing mechanisms respectively corresponding to the plurality of liners, each fixing mechanism being configured to fix a corresponding liner to the sidewall of the chamber.

(13) The substrate processing apparatus of (12), wherein the gap is formed obliquely with respect to a radial direction.

(14) The substrate processing apparatus of (12), wherein the gap has a labyrinth-shaped structure having a plurality of folded portions.

(15) The substrate processing apparatus of any one of (12) to (14), wherein the number of the liners is 3 to 30.

(16) The substrate processing apparatus of any one of (12) to (15), wherein the liner has a through hole penetrating from the first surface to the second surface, and the fixing mechanism includes at least one bolt inserted into the through hole.

(17) The substrate processing apparatus of (16), wherein the through hole is formed substantially at a center of the liner in a horizontal direction.

(18) The substrate processing apparatus of any one of (12) to (17), wherein the second surface has a first curvature in plan view.

(19) A substrate processing apparatus comprising: a chamber made of a conductive material and connected to a ground potential; a plurality of liners made of an insulating material and arranged in a circumferential direction in the chamber, each liner having a first surface and a second surface opposite to the first surface, the first surface being in contact with a sidewall of the chamber, a gap being formed between two adjacent liners among the plurality of liners; and a plurality of fixing mechanism respectively corresponding to the plurality of liners, each fixing mechanism being configured to fix a corresponding liner to the sidewall of the chamber.

(20) The substrate processing apparatus of (19), wherein the insulating material is quartz.

1. A plasma processing apparatus comprising:
a conductive chamber made of a first conductive material and connected to a ground potential;
a plasma generator configured to generate a plasma in the conductive chamber;
a plurality of conductive liners made of a second conductive material different from the first conductive material and arranged in a circumferential direction in the conductive chamber, each conductive liner having a first surface and a second surface opposite to the first surface, the first surface being in contact with a sidewall of the conductive chamber, the second surface being exposed to the plasma, a gap being formed between two adjacent conductive liners among the plurality of conductive liners; and
a plurality of fixing mechanisms respectively corresponding to the plurality of conductive liners, each fixing mechanism being configured to fix a corresponding conductive liner to the sidewall of the conductive chamber.

2. The plasma processing apparatus of claim 1, wherein the gap is formed obliquely with respect to a radial direction.

3. The plasma processing apparatus of claim 1, wherein the gap has a labyrinth-shaped structure having a plurality of folded portions.

4. The plasma processing apparatus of claim 1, wherein the number of the conductive liners is 3 to 30.

5. The plasma processing apparatus of claim 1, wherein the conductive liner has a through hole penetrating from the first surface to the second surface, and
the fixing mechanism includes at least one bolt inserted into the through hole.

6. The plasma processing apparatus of claim 5, wherein the through hole is formed substantially at a center of the conductive liner in a horizontal direction.

7. The plasma processing apparatus of claim 1, wherein the second surface has a first curvature in plan view.

8. The plasma processing apparatus of claim 7, wherein an inner surface of the sidewall of the conductive chamber has a plurality of flat surfaces, and
the first surface is a flat surface.

9. The plasma processing apparatus of claim 7, wherein an inner surface of the sidewall of the conductive chamber has a circular shape in plan view, and
the first surface has a second curvature in plan view.

10. The plasma processing apparatus of claim 1, wherein the second conductive material is Si or SiC.

11. The plasma processing apparatus of claim 10, wherein the first conductive material is a metal.

12. A substrate processing apparatus comprising:
a chamber made of a metal and connected to a ground potential;
a plurality of liners made of Si or SiC and arranged in a circumferential direction in the chamber, each liner having a first surface and a second surface opposite to the first surface, the first surface being in contact with a sidewall of the chamber, a gap being formed between two adjacent lines among the plurality of liners; and
a plurality of fixing mechanisms respectively corresponding to the plurality of liners, each fixing mechanism being configured to fix a corresponding liner to the sidewall of the chamber.

13. The substrate processing apparatus of claim 12, wherein the gap is formed obliquely with respect to a radial direction.

14. The substrate processing apparatus of claim 12, wherein the gap has a labyrinth-shaped structure having a plurality of folded portions.

15. The substrate processing apparatus of claim 12, wherein the number of the liners is 3 to 30.

16. The substrate processing apparatus of claim 12, wherein the liner has a through hole penetrating from the first surface to the second surface, and
the fixing mechanism includes at least one bolt inserted into the through hole.

17. The substrate processing apparatus of claim 16, wherein the through hole is formed substantially at a center of the liner in a horizontal direction.

18. The substrate processing apparatus of claim 12, wherein the second surface has a first curvature in plan view.

19. A substrate processing apparatus comprising:
a chamber made of a conductive material and connected to a ground potential;
a plurality of liners made of an insulating material and arranged in a circumferential direction in the chamber, each liner having a first surface and a second surface opposite to the first surface, the first surface being in contact with a sidewall of the chamber, a gap being formed between two adjacent liners among the plurality of liners; and
a plurality of fixing mechanism respectively corresponding to the plurality of liners, each fixing mechanism being configured to fix a corresponding liner to the sidewall of the chamber.

20. The substrate processing apparatus of claim 19, wherein the insulating material is quartz.
